(19) United States
(12) Patent Application Publication
(10) Pub. No.: US 2003/0091930 A1
(43) Pub. Date: May 15, 2003

(54) Pattern formation material and pattern formation method

(75) Inventors: Shinji Kishimura, Hyogo (JP); Masayuki Endo, Osaka (JP); Masaru Sasago, Osaka (JP); Mitsuru Ueda, Tokyo (JP); Tsuyohiko Fujigaya, Saitama (JP)

Correspondence Address: NIXON PEABODY, LLP, 8180 GREENSBORO DRIVE, SUITE 800, MCLEAN, VA, 22102, US

(73) Assignee: MATSUSHITA ELECTRIC INDUSTRIAL CO., LTD., Osaka (JP)

(21) Appl. No.: 10/241,758

(22) Filed: Sep. 12, 2002

(30) Foreign Application Priority Data
Sep. 13, 2001 (JP) 2001-277597

(51) Int. Cl. G03F 7/038

(52) U.S. Cl. 430/270.1; 430/311

(57) ABSTRACT

A pattern formation material of this invention contains a base polymer including a unit represented by Chemical Formula 1 and an acid generator:

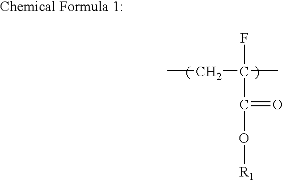

wherein R₁ is a protecting group released by an acid.

### BACKGROUND OF THE INVENTION

The present invention relates to a pattern formation method and a pattern formation material, and more particularly, it relates to a pattern formation method for forming a resist pattern, used for forming a semiconductor device or a semiconductor integrated circuit on a semiconductor substrate, by using exposing light of a wavelength not longer than a 180 nm band and a pattern formation material used in the pattern formation method.

Currently, in fabrication of a mass storage semiconductor integrated circuit, such as a 64 Mbit dynamic random access memory (DRAM) and a logic device or a system LSI with a 0.25 μm through 0.15 μm rule, a resist pattern is formed by using a chemically amplified resist material including a polyhydroxystyrene derivative and an acid generator as principal constituents with KrF excimer laser (of a wavelength of a 248 nm band) used as exposing light.

Moreover, for fabrication of a 256 Mbit DRAM, a 1 Gbit DRAM or a system LSI with a 0.15 μm through 0.13 μm rule, a pattern formation method using, as exposing light, ArF excimer laser lasing at a shorter wavelength (of a 193 nm band) than the KrF excimer laser is now under development.

The chemically amplified resist material including a polyhydroxystyrene derivative as a principal constituent has high absorbance against light of a wavelength of a 193 nm band because of an aromatic ring included therein. Therefore, exposing light of a wavelength of a 193 nm band cannot uniformly reach the bottom of a resist film, and hence, a pattern cannot be formed in a good shape. Accordingly, the chemically amplified resist material including a polyhydroxystyrene derivative as a principal constituent cannot be used when the ArF excimer laser is used as the exposing light.

Therefore, a chemically amplified resist material including, as a principal constituent, a polyacrylic acid derivative or a polycycloolefin derivative having no aromatic ring is used when the ArF excimer laser is used as the exposing light.

On the other hand, as exposing light for a pattern formation method capable of coping with high resolution, an electron beam (EB) and the like are being examined.

When the EB is used as the exposing light, however, the throughput is disadvantageously low, and hence, the EB is not suitable to mass production. Thus, the EB is not preferred as the exposing light.

Accordingly, in order to form a resist pattern finer than 0.10 μm, it is necessary to use exposing light of a wavelength shorter than that of the ArF excimer laser, such as Xe₂ laser (of a wavelength of a 172 nm band), F₂ laser (of a wavelength of a 157 nm band), Kr₂ laser (of a wavelength of a 146 nm band), ArKr laser (of a wavelength of 134 nm band), Ar₂ laser (of a wavelength of a 126 nm band), soft X-rays (of a wavelength of a 13, 11 or 5 nm band) and hard X-rays (of a wavelength not longer than a 1 nm band). In other words, a resist pattern is required to be formed by using exposing light of a wavelength not longer than a 180 nm band.

Therefore, the present inventors have formed resist patterns by conducting pattern exposure using F₂ laser ( of a wavelength of a 157 nm band) on resist films formed from conventionally known chemically amplified resist materials respectively including a polyhydroxystyrene derivative represented by Chemical Formula A, a polyacrylic acid derivative represented by Chemical Formula B and a polycycloolefin derivative represented by Chemical Formula C.

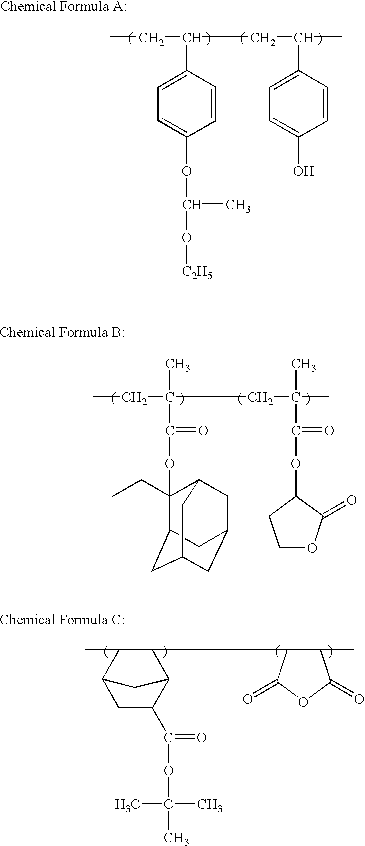

Now, a method for forming a resist pattern by using any of the aforementioned conventional chemically amplified resist materials and problems arising in the conventional method will be described with reference to FIGS. 2A through 2D.

First, as shown in FIG. 2A, the chemically amplified resist material is applied on a semiconductor substrate 1 by spin coating and the resultant is heated, so as to form a resist film 2 with a thickness of 0.3 μm. Thereafter, as shown in FIG. 2B, the resist film 2 is irradiated with a F₂ laser beam 4 through a mask 3 for pattern exposure. Thus, an acid is generated from the acid generator in an exposed portion 2a of the resist film 2 while no acid is generated in an unexposed portion 2b of the resist film 2.

Next, as shown in FIG. 2C, the semiconductor substrate 1 is heated with a hot plate 5 at, for example 100° C. for 60 seconds.

Then, the resist film 2 is developed with an alkaline developer, thereby forming a resist pattern 6 as shown in FIG. 2D.

However, as shown in FIG. 2D, the resist pattern 6 cannot be formed in a good pattern shape, and there remains much scum on the semiconductor substrate 1. Such problems occur not only in using the F₂ laser beam as the exposing light but also in using any of the other light of a wavelength not longer than a 180 nm band.

Accordingly, a resist pattern cannot be practically formed by irradiating a resist film formed from any of the aforementioned chemically amplified resist materials with light of a wavelength not longer than a 180 nm band.

### SUMMARY OF THE INVENTION

In consideration of the aforementioned conventional problems, an object of the invention is forming a resist pattern in a good pattern shape by using exposing light of a wavelength not longer than a 180 nm band with minimally producing scum.

The present inventors have studied the cause of the conventional problems occurring in using the conventional chemically amplified resist materials and have found the following:

First, the chemically amplified resist materials have high absorbance against light of a wavelength not longer than a 180 nm band. For example, a resist film with a thickness of 100 nm formed from the chemically amplified resist material including a polyhydroxystyrene derivative has transmittance of 20% at most against a F₂ laser beam (of a wavelength of a 157 nm band).

Therefore, various examination has been made on means for improving the transmittance of a chemically amplified resist material against light of a wavelength not longer than a 180 nm band. As a result, it has been found that a unit represented by Chemical Formula 1 below can improve the transmittance against light of a wavelength not longer than a 180 nm band.

The present invention was devised on the basis of the aforementioned finding, and specifically provides pattern formation materials and methods described below.

The first pattern formation material of this invention comprises a base polymer including a unit represented by Chemical Formula 1; and an acid generator:

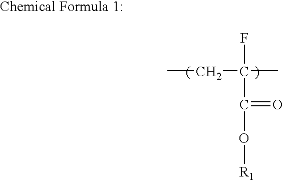

wherein R₁ is a protecting group released by an acid.

Since the base polymer of the first pattern formation material includes the unit represented by Chemical Formula 1, the transmittance of a resist film against light of a wavelength not longer than a 180 nm band can be improved. Also, when the protecting group is released from the unit represented by Chemical Formula 1, acrylic acid having a fluorine atom at the α-position is generated, and hence, the solubility in a developer can be improved. Therefore, the contrast in the solubility between an exposed portion and an unexposed portion of the resist film can be improved.

The second pattern formation material of this invention comprises a base polymer including a unit represented by Chemical Formula 2 and a unit represented by Chemical Formula 3; and an acid generator:

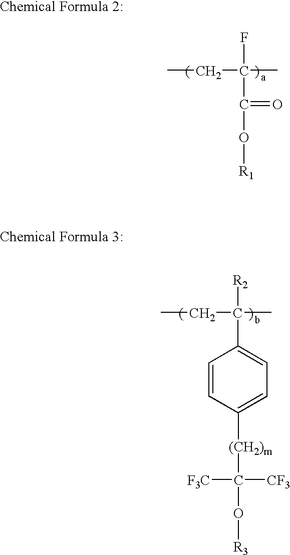

wherein R₁ is a protecting group released by an acid; R₂ is a hydrogen atom, a chlorine atom, a fluorine atom, an alkyl group or an alkyl group including a fluorine atom; R₃ is an alkyl group, a cyclic aliphatic group, an aromatic group, a heterocycle, an ester group or an ether group; m is an integer of 0 through 5; and a and b satisfy 0<a<1, 0<b<1 and 0<a+b≦1.

Since the base polymer of the second pattern formation material includes the unit represented by Chemical Formula 2, the transmittance of a resist film against light of a wavelength not longer than a 180 nm band can be improved and the contrast in the solubility between an exposed portion and an unexposed portion of the resist film can be improved similarly to the first pattern formation material.

In particular, since the base polymer of the second pattern formation material includes the unit represented by Chemical Formula 3, the transmittance of the resist film against light of a wavelength not longer than a 180 nm band can be largely improved. Also, when R₃ is released by the function of an acid from the unit represented by Chemical Formula 3, hexafluoroisopropyl alcohol is generated, and hence, the solubility of the exposed portion of the resist film in a developer can be improved. Therefore, the contrast in the solubility between the exposed portion and the unexposed portion of the resist film can be largely improved. Furthermore, since the unit represented by Chemical Formula 3 has a benzene ring, resistance against dry etching can be improved.

The third pattern formation material of this invention comprises a base polymer including a unit represented by Chemical Formula 2 and a unit represented by Chemical Formula 4; and an acid generator:

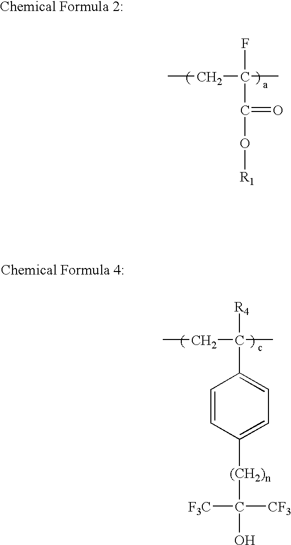

wherein R₁ is a protecting group released by an acid; R₄ is a hydrogen atom, a chlorine atom, a fluorine atom, an alkyl group or an alkyl group including a fluorine atom; n is an integer of 0 through 5; and a and c satisfy 0<a<1, 0<c<1 and 0<a+c≦1.

Since the base polymer of the third pattern formation material includes the unit represented by Chemical Formula 2, the transmittance of a resist film against light of a wavelength not longer than a 180 nm band can be improved and the contrast in the solubility between an exposed portion and an unexposed portion of the resist film can be improved similarly to the first pattern formation material.

In particular, since the base polymer of the third pattern formation material includes the unit represented by Chemical Formula 4, the transmittance of the resist film against light of a wavelength not longer than a 180 nm band can be largely improved. Also, since the unit represented by Chemical Formula 4 has hexafluoroisopropyl alcohol, the solubility of the exposed portion of the resist film in a developer can be improved, so as to largely improve the contrast in the solubility between the exposed portion and the unexposed portion of the resist film, and the wettability of the resist film can be improved so as to improve the adhesion between the resist film and a substrate. Furthermore, since the unit represented by Chemical Formula 4 has a benzene ring, the resistance against dry etching can be improved.

The fourth pattern formation material of this invention comprises a base polymer including a unit represented by Chemical Formula 2, a unit represented by Chemical Formula 3 and a unit represented by Chemical Formula 4; and an acid generator:

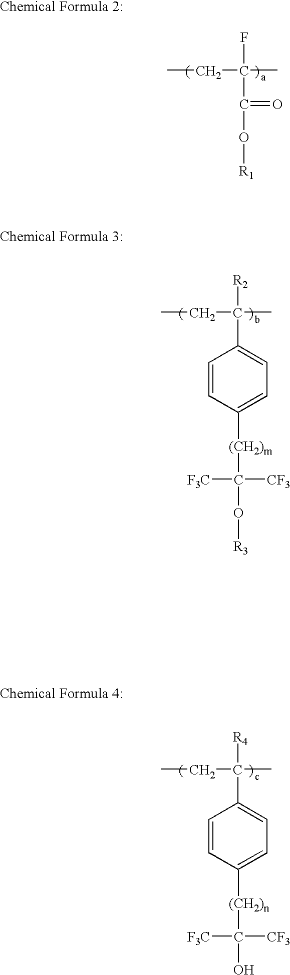

wherein R₁ is a protecting group released by an acid; R₂ and R₄ are the same or different and are selected from the group consisting of a hydrogen atom, a chlorine atom, a fluorine atom, an alkyl group and an alkyl group including a fluorine atom; R₃ is an alkyl group, a cyclic aliphatic group, an aromatic group, a heterocycle, an ester group or an ether group; m and n are integers of 0 through 5; and a, b and c satisfy 0<a<1, 0<b<1, 0<c<1 and 0<a+b+c≦1.

Since the base polymer of the fourth pattern formation material includes the unit represented by Chemical Formula 2, the transmittance of a resist film against light of a wavelength not longer than a 180 nm band can be improved and the contrast in the solubility between an exposed portion and an unexposed portion of the resist film can be improved similarly to the first pattern formation material.

In particular, since the base polymer of the fourth pattern formation material includes the unit represented by Chemical Formula 3 and the unit represented by Chemical Formula 4, the characteristics of the second pattern formation material and the characteristics of the third pattern formation material are both exhibited. Therefore, the transmittance of the resist film against light of a wavelength not longer than a 180 nm band and the contrast in the solubility between the exposed portion and the unexposed portion of the resist film can be further improved, the adhesion between the resist film and a substrate can be improved and the resistance against dry etching can be largely improved.

The fifth pattern formation material of this invention comprises a base polymer including a unit represented by Chemical Formula 2 and a unit represented by Chemical Formula 5; and an acid generator:

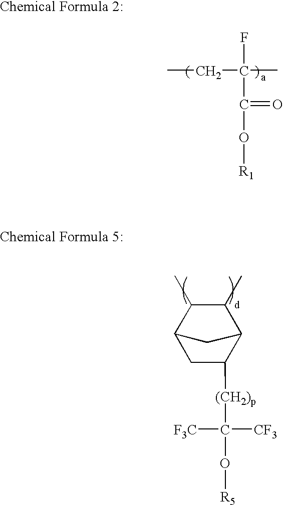

wherein R₁ is a protecting group released by an acid; R₅ is an alkyl group, a cyclic aliphatic group, an aromatic group, a heterocycle, an ester group or an ether group; p is an integer of 0 through5; and a and d satisfy 0<a<1, 0<d<1 and 0<a+d≦1.

Since the base polymer of the fifth pattern formation material includes the unit represented by Chemical Formula 2, the transmittance of a resist film against light of a wavelength not longer than a 180 nm band can be improved and the contrast in the solubility between an exposed portion and an unexposed portion of the resist film can be improved similarly to the first pattern formation material.

In particular, since the base polymer of the fifth pattern formation material includes the unit represented by Chemical Formula 5, namely, the base polymer has a norbornene ring, the transmittance of the resist film against light of a wavelength not longer than a 180 nm band can be further improved. Also, when R₅ is released by the function of an acid from the unit represented by Chemical Formula 5, hexafluoroisopropyl alcohol is generated, and hence, the solubility of the exposed portion of the resist film in a developer can be improved. Therefore, the contrast in the solubility between the exposed portion and the unexposed portion of the resist film can be further improved. Moreover, since the unit represented by Chemical Formula 5 has a norbornene ring, the resistance against dry etching can be improved.

The sixth pattern formation material of this invention comprises a base polymer including a unit represented by Chemical Formula 2 and a unit represented by Chemical Formula 6; and an acid generator:

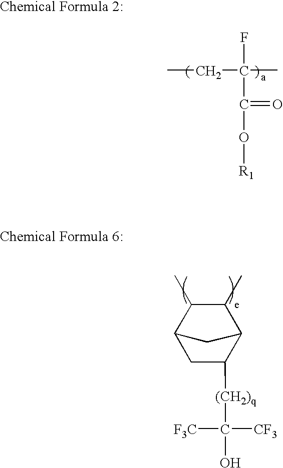

wherein R₁ is a protecting group released by an acid; q is an integer of 0 through 5; and a and e satisfy 0<a<1, 0<e<1 and 0<a+e≦1.

Since the base polymer of the sixth pattern formation material includes the unit represented by Chemical Formula 2, the transmittance of a resist film against light of a wavelength not longer than a 180 nm band can be improved and the contrast in the solubility between an exposed portion and an unexposed portion of the resist film can be improved similarly to the first pattern formation material.

In particular, since the base polymer of the sixth pattern formation material includes the unit represented by Chemical Formula 6, namely, the base polymer has a norbornene ring, the transmittance of the resist film against light of a wavelength not longer than a 180 nm band can be further improved. Also, since the unit represented by Chemical Formula 6 has hexafluoroisopropyl alcohol, the solubility of the exposed portion of the resist film in a developer can be improved, so as to largely improve the contrast in the solubility between the exposed portion and the unexposed portion of the resist film, and the wettability of the resist film can be improved so as to improve the adhesion between the resist film and a substrate. Moreover, since the unit represented by Chemical Formula 6 has a norbornene ring, the resistance against dry etching can be improved.

The seventh pattern formation material of this invention comprises a base polymer including a unit represented by Chemical Formula 2, a unit represented by Chemical Formula 5 and a unit represented by Chemical Formula 6; and an acid generator:

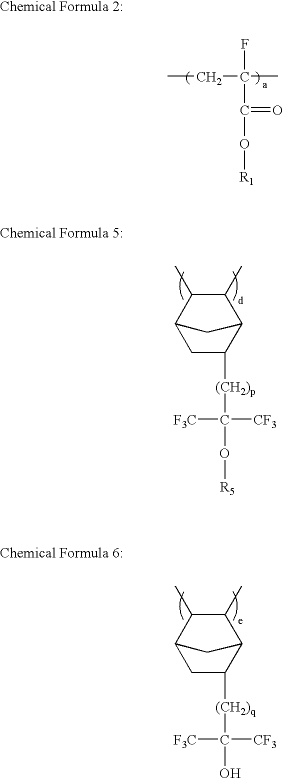

wherein R₁ is a protecting group released by an acid; R₅ is an alkyl group, a cyclic aliphatic group, an aromatic group, a heterocycle, an ester group or an ether group; p and q are integers of 0 through 5; and a, d and e satisfy 0<a<1, 0<d<1, 0<e<1 and 0<a+d+e≦1.

Since the base polymer of the seventh pattern formation material includes the unit represented by Chemical Formula 2, the transmittance of a resist film against light of a wavelength not longer than a 180 nm band can be improved and the contrast in the solubility between an exposed portion and an unexposed portion of the resist film can be improved similarly to the first pattern formation material.

In particular, since the base polymer of the seventh pattern formation material includes the unit represented by Chemical Formula 5 and the unit represented by Chemical Formula 6, the characteristics of the fifth pattern formation material and the characteristics of the sixth pattern formation material are both exhibited. Therefore, the transmittance of the resist film against light of a wavelength not longer than a 180 nm band and the contrast in the solubility between the exposed portion and the unexposed portion of the resist film can be further improved, the adhesion between the resist film and a substrate can be improved and the resistance against dry etching can be largely improved.

The first pattern formation method of this invention comprises the steps of forming a resist film by applying the first pattern formation material on a substrate; irradiating the resist film with exposing light of a wavelength not longer than a 180 nm band for pattern exposure; and forming a resist pattern by developing the resist film after the pattern exposure.

Since the first pattern formation material is used in the first pattern formation method, the transmittance of the resist film against light of a wavelength not longer than a 180 nm band can be improved and the contrast in the solubility between an exposed portion and an unexposed portion of the resist film can be improved.

The second pattern formation method of this invention comprises the steps of forming a resist film by applying the second pattern formation material on a substrate; irradiating the resist film with exposing light of a wavelength not longer than a 180 nm band for pattern exposure; and forming a resist pattern by developing the resist film after the pattern exposure.

Since the second pattern formation material is used in the second pattern formation method, the transmittance of the resist film against light of a wavelength not longer than a 180 nm band and the contrast in the solubility between an exposed portion and an unexposed portion of the resist film can be largely improved and the resistance against dry etching can be improved.

The third pattern formation method of this invention comprises the steps of forming a resist film by applying the third pattern formation material on a substrate; irradiating the resist film with exposing light of a wavelength not longer than a 180 nm band for pattern exposure; and forming a resist pattern by developing the resist film after the pattern exposure.

Since the third pattern formation material is used in the third pattern formation method, the transmittance of the resist film against light of a wavelength not longer than a 180 nm band and the contrast in the solubility between an exposed portion and an unexposed portion of the resist film can be largely improved, and the adhesion between the resist film and the substrate and the resistance against dry etching can be improved.

The fourth pattern formation method of this invention comprises the steps of forming a resist film by applying the fourth pattern formation material on a substrate; irradiating the resist film with exposing light of a wavelength not longer than a 180 nm band for pattern exposure; and forming a resist pattern by developing the resist film after the pattern exposure.

Since the fourth pattern formation material is used in the fourth pattern formation method, the transmittance of the resist film against light of a wavelength not longer than a 180 nm band and the contrast in the solubility between an exposed portion and an unexposed portion of the resist film can be further improved, and the adhesion between the resist film and the substrate can be improved and the resistance against dry etching can be largely improved.

The fifth pattern formation method of this invention comprises the steps of forming a resist film by applying the fifth pattern formation material on a substrate; irradiating the resist film with exposing light of a wavelength not longer than a 180 nm band for pattern exposure; and forming a resist pattern by developing the resist film after the pattern exposure.

Since the fifth pattern formation material is used in the fifth pattern formation method, the transmittance of the resist film against light of a wavelength not longer than a 180 nm band and the contrast in the solubility between an exposed portion and an unexposed portion of the resist film can be largely improved and the resistance against dry etching can be improved.

The sixth pattern formation method of this invention comprises the steps of forming a resist film by applying the sixth pattern formation material on a substrate; irradiating the resist film with exposing light of a wavelength not longer than a 180 nm band for pattern exposure; and forming a resist pattern by developing the resist film after the pattern exposure.

Since the sixth pattern formation material is used in the sixth pattern formation method, the transmittance of the resist film against light of a wavelength not longer than a 180 nm band and the contrast in the solubility between an exposed portion and an unexposed portion of the resist film can be largely improved, and the adhesion between the resist film and the substrate and the resistance against dry etching can be improved.

The seventh pattern formation method of this invention comprises the steps of forming a resist film by applying the seventh pattern formation material on a substrate; irradiating the resist film with exposing light of a wavelength not longer than a 180 nm band for pattern exposure; and forming a resist pattern by developing the resist film after the pattern exposure.

Since the seventh pattern formation material is used in the seventh pattern formation method, the transmittance of the resist film against light of a wavelength not longer than a 180 nm band and the contrast in the solubility between an exposed portion and an unexposed portion of the resist film can be further improved, the adhesion between the resist film and the substrate can be improved and the resistance against dry etching can be largely improved.

In any of the first through seventh pattern formation methods, the exposing light may be light of a wavelength of a 110 through 180 nm band, such as a Xe₂ laser beam, a F₂ laser beam, a Kr₂ laser beam, an ArKr laser beam or an Ar₂ laser beam, a soft X-ray beam of a wavelength of a 1 through 30 nm band, or a hard X-ray beam of a wavelength not longer than a 1 nm band.

### BRIEF DESCRIPTION OF THE DRAWINGS

FIGS. 1A, 1B, 1C and 1D are cross-sectional views for showing procedures in a pattern formation method according to any of Embodiments 1 through 7 of the invention; and

FIGS. 2A, 2B, 2C and 2D are cross-sectional views for showing procedures in a conventional pattern formation method.

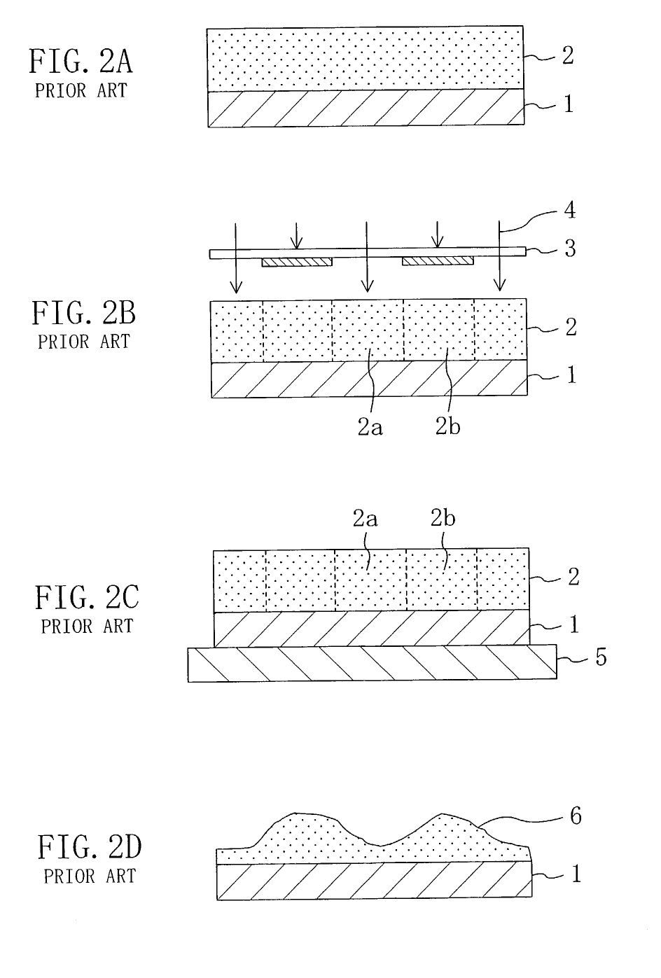

### DETAILED DESCRIPTION OF THE INVENTION

Embodiment 1

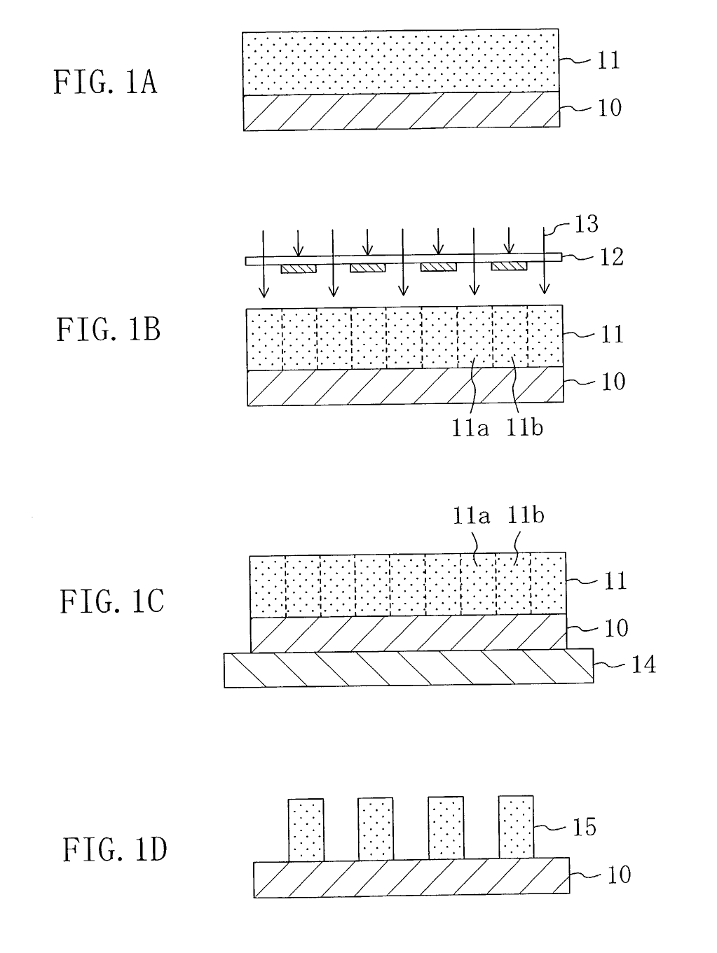

A pattern formation material and a pattern formation method according to Embodiment 1 of the invention will now be described with reference to FIGS. 1A through 1D.

In this embodiment, the first pattern formation material and the first pattern formation method described above are embodied, and the specific composition of a resist material of this embodiment is as follows:

Base polymer: a polymer represented by Chemical Formula 7 below

Acid generator: triphenylsulfonium triflate (5 wt % based on the base polymer)

Solvent: propylene glycol monomethyl ether acetate

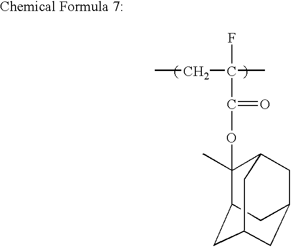

Chemical Formula 7 represents a specific example of a base polymer including the above-described unit represented by Chemical Formula 1.

In the unit represented by Chemical Formula 1, R₁ may be, for example, any of protecting groups represented by Chemical Formula 8 below.

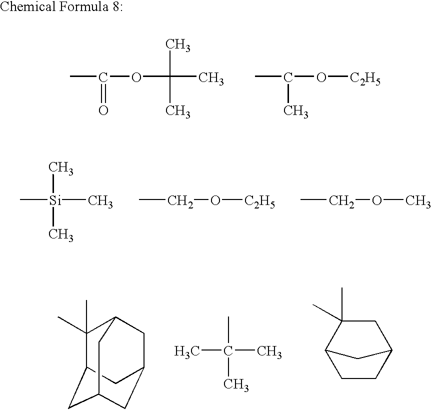

First, as shown in FIG. 1A, the resist material having the above-described composition is applied on a semiconductor substrate 10 by spin coating, thereby forming a resist film 11 with a thickness of 0.2 μm. At this point, since the base polymer is alkali-refractory, the resist film 11 is alkali-refractory.

Next, as shown in FIG. 1B, the resist film 11 is subjected to pattern exposure by irradiating through a mask 12 with F₂ laser 13 (of a wavelength of a 157 nm band). Thus, an acid is generated from the acid generator in an exposed portion 11a of the resist film 11 while no acid is generated in an unexposed portion 11b of the resist film 11.

Then, as shown in FIG. 1C, the semiconductor substrate 10 together with the resist film 11 is heated with a hot plate 14. Thus, the base polymer is heated in the presence of the acid in the exposed portion 11a of the resist film 11, so as to release a protecting group from the base polymer of Chemical Formula 7. As a result, the base polymer becomes alkali-soluble.

Subsequently, the resist film 11 is developed with an alkaline developer such as a tetramethylammonium hydroxide aqueous solution. Thus, the exposed portion 11a of the resist film 11 is dissolved in the developer, so that a resist pattern 15 can be formed from the unexposed portion 11b of the resist film 11 as shown in FIG. 1D.

Embodiment 2

A pattern formation material and a pattern formation method according to Embodiment 2 of the invention will now be described. Embodiment 2 is different from Embodiment 1 in the resist material alone, and hence, the resist material alone will be herein described.

In this embodiment, the second pattern formation material and the second pattern formation method described above are embodied, and the specific composition of the resist material is as follows:

Base polymer: a polymer represented by Chemical Formula 9 below

Acid generator: triphenylsulfonium triflate (5 wt % based on the base polymer)

Solvent: propylene glycol monomethyl ether acetate

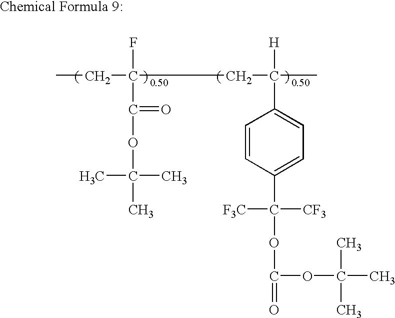

Chemical Formula 9 represents a specific example of a base polymer including the above-described units respectively represented by Chemical Formulas 2 and 3.

In the unit represented by Chemical Formula 2, R₁ may be, for example, any of the protecting groups represented by Chemical Formula 8.

In the unit represented by Chemical Formula 3, R₂ is a hydrogen atom, and alternatively, R₂ may be a chlorine atom, a fluorine atom, an alkyl group or an alkyl group including a fluorine atom.

In the unit represented by Chemical Formula 3, R₃ may be an alkyl group, a cyclic aliphatic group, an aromatic group, a heterocycle, an ester group or an ether group. In the case where R₃ of the unit represented by Chemical Formula 3 is a substituent group used in Chemical Formula 9, the substituent group is released by an acid.

Also, although m is 0 in the unit represented by Chemical Formula 3, m may be an integer of 1 through 5 instead.

Embodiment 3

A pattern formation material and a pattern formation method according to Embodiment 3 of the invention will now be described. Embodiment 3 is different from Embodiment 1 in the resist material alone, and hence, the resist material alone will be herein described.

In this embodiment, the third pattern formation material and the third pattern formation method described above are embodied, and the specific composition of the resist material is as follows:

Base polymer: a polymer represented by Chemical Formula 10 below

Acid generator: triphenylsulfonium triflate (5 wt % based on the base polymer)

Solvent: propylene glycol monomethyl ether acetate

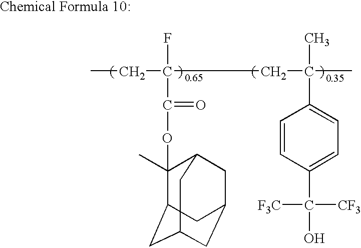

Chemical Formula 10 represents a specific example of a base polymer including the above-described units respectively represented by Chemical Formulas 2 and 4.

In the unit represented by Chemical Formula 2, R₁ may be, for example, any of the protecting groups represented by Chemical Formula 8.

In the unit represented by Chemical Formula 4, R₄ is a methyl group, and alternatively, R₄ may be a hydrogen atom, a chlorine atom, a fluorine atom, an alkyl group or an alkyl group including a fluorine atom.

Also, although n is 0 in the unit represented by Chemical Formula 4, n may be an integer of 1 through 5 instead.

Embodiment 4

A pattern formation material and a pattern formation method according to Embodiment 4 of the invention will now be described. Embodiment 4 is different from Embodiment 1 in the resist material alone, and hence, the resist material alone will be herein described.

In this embodiment, the fourth pattern formation material and the fourth pattern formation method described above are embodied, and the specific composition of the resist material is as follows:

Base polymer: a polymer represented by Chemical Formula 11 below

Acid generator: triphenylsulfonium triflate (5 wt % based on the base polymer)

Solvent: propylene glycol monomethyl ether acetate

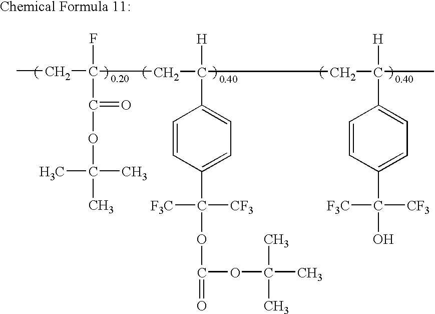

Chemical Formula 11 represents a specific example of a base polymer including the above-described units respectively represented by Chemical Formulas 2, 3 and 4.

In the unit represented by Chemical Formula 2, R₁ may be, for example, any of the protecting groups represented by Chemical Formula 8.

In the units represented by Chemical Formulas 3 and 4, R₂ and R₄ are both a hydrogen atom, and alternatively, they may be the same or different and selected from the group consisting of a chlorine atom, a fluorine atom, an alkyl group and an alkyl group including a fluorine atom.

In the unit represented by Chemical Formula 3, R₃ may be an alkyl group, a cyclic aliphatic group, an aromatic group, a heterocycle, an ester group or an ether group. In the case where R₃ of the unit represented by Chemical Formula 3 is a substituent group used in Chemical Formula 11, the substituent group is released by an acid.

Also, although m is 0 in the unit represented by Chemical Formula 3, m may be an integer of 1 through 5 instead.

Although n is 0 in the unit represented by Chemical Formula 4, n may be an integer of 1 through 5 instead.

Embodiment 5

A pattern formation material and a pattern formation method according to Embodiment 5 of the invention will now be described. Embodiment 5 is different from Embodiment 1 in the resist material alone, and hence, the resist material alone will be herein described.

In this embodiment, the fifth pattern formation material and the fifth pattern formation method described above are embodied, and the specific composition of the resist material is as follows:

Base polymer: a polymer represented by Chemical Formula 12 below

Acid generator: triphenylsulfonium triflate (5 wt % based on the base polymer)

Solvent: propylene glycol monomethyl ether acetate

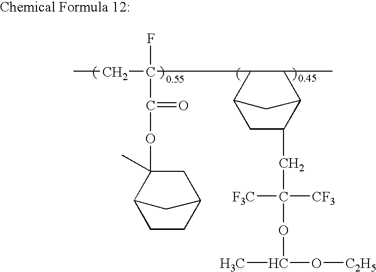

Chemical Formula 12 represents a specific example of a base polymer including the above-described units respectively represented by Chemical Formulas 2 and 5.

In the unit represented by Chemical Formula 2, R₁ may be, for example, any of the protecting groups represented by Chemical Formula 8.

In the unit represented by Chemical Formula 5, R₅ may be an alkyl group, a cyclic aliphatic group, an aromatic group, a heterocycle, an ester group or an ether group.

Also, although p is 1 in the unit represented by Chemical Formula 5, p may be 0 or an integer of 2 through 5 instead.

Embodiment 6

A pattern formation material and a pattern formation method according to Embodiment 6 of the invention will now be described. Embodiment 6 is different from Embodiment 1 in the resist material alone, and hence, the resist material alone will be herein described.

In this embodiment, the sixth pattern formation material and the sixth pattern formation method described above are embodied, and the specific composition of the resist material is as follows:

Base polymer: a polymer represented by Chemical Formula 13 below

Acid generator: triphenylsulfonium triflate (5 wt % based on the base polymer)

Solvent: propylene glycol monomethyl ether acetate

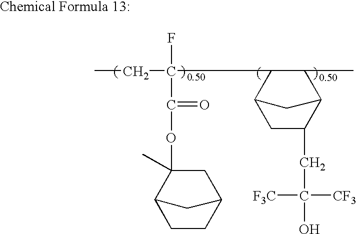

Chemical Formula 13 represents a specific example of a base polymer including the above-described units respectively represented by Chemical Formulas 2 and 6.

In the unit represented by Chemical Formula 2, R₁ may be, for example, any of the protecting groups represented by Chemical Formula 8.

Also, although q is 1 in the unit represented by Chemical Formula 6, q may be 0 or an integer of 2 through 5 instead.

Embodiment 7

A pattern formation material and a pattern formation method according to Embodiment 7 of the invention will now be described. Embodiment 7 is different from Embodiment 1 in the resist material alone, and hence, the resist material alone will be herein described.

In this embodiment, the seventh pattern formation material and the seventh pattern formation method described above are embodied, and the specific composition of the resist material is as follows:

Base polymer: a polymer represented by Chemical Formula 14 below

Acid generator: triphenylsulfonium triflate (5 wt % based on the base polymer)

Solvent: propylene glycol monomethyl ether acetate

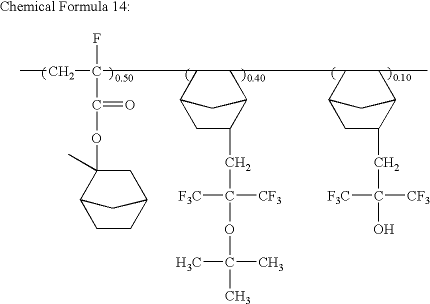

Chemical Formula 14 represents a specific example of a base polymer including the above-described units respectively represented by Chemical Formulas 2, 5 and 6.

In the unit represented by Chemical Formula 2, R₁ may be, for example, any of the protecting groups represented by Chemical Formula 8.

In the unit represented by Chemical Formula 5, R₅ may be an alkyl group, a cyclic aliphatic group, an aromatic group, a heterocycle, an ester group or an ether group.

Also, although p is 1 in the unit represented by Chemical Formula 5, p may be 0 or an integer of 2 through 5 instead.

Although q is 1 in the unit represented by Chemical Formula 6, q may be 0 or an integer of 2 through 5 instead.

Although the F₂ laser beam is used as the exposing light in Embodiments 1 through 7, the exposing light may be light of a wavelength of a 110 through 180 nm band, such as a Xe₂ laser beam, a Kr₂ laser beam, an ArKr laser beam and an Ar₂ laser beam, a soft X-ray beam of a wavelength of a 1 through 30 nm band or a hard X-ray beam of a wavelength not longer than a 1 nm band.

What is claimed is:

1. A pattern formation material comprising:
a base polymer including a unit represented by Chemical Formula 1; and
an acid generator: 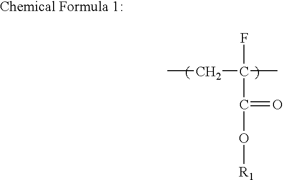
wherein R₁ is a protecting group released by an acid.

2. A pattern formation material comprising:
a base polymer including a unit represented by Chemical Formula 2 and a unit represented by Chemical Formula 3; and
an acid generator: 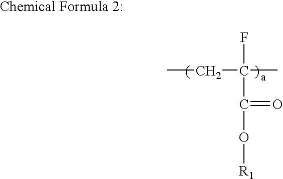 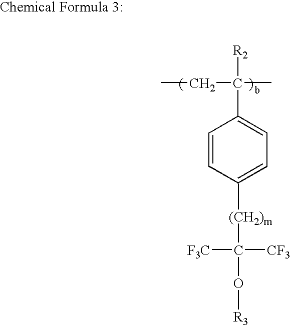
wherein R₁ is a protecting group released by an acid; R₂ is a hydrogen atom, a chlorine atom, a fluorine atom, an alkyl group or an alkyl group including a fluorine atom; R₃ is an alkyl group, a cyclic aliphatic group, an aromatic group, a heterocycle, an ester group or an ether group; m is an integer of 0 through 5; and a and b satisfy 0<a<1, 0<b<1 and 0<a+b≦1.

3. A pattern formation material comprising:
a base polymer including a unit represented by Chemical Formula 2 and a unit represented by Chemical Formula 4; and
an acid generator: 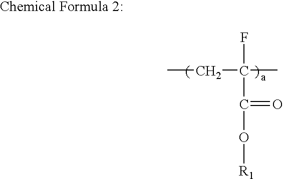 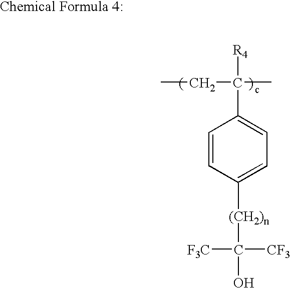
wherein R₁ is a protecting group released by an acid; R₄ is a hydrogen atom, a chlorine atom, a fluorine atom, an alkyl group or an alkyl group including a fluorine atom; n is an integer of 0 through 5; and a and c satisfy 0<a<1, 0<c<1 and 0<a+c≦1.

4. A pattern formation material comprising:
a base polymer including a unit represented by Chemical Formula 2, a unit represented by Chemical Formula 3 and a unit represented by Chemical Formula 4; and
an acid generator: 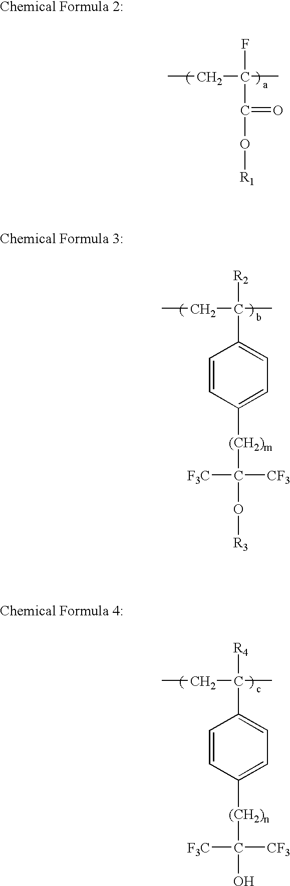
wherein R₁ is a protecting group released by an acid; R₂ and R₄ are the same or different and are selected from the group consisting of a hydrogen atom, a chlorine atom, a fluorine atom, an alkyl group and an alkyl group including a fluorine atom; R₃ is an alkyl group, a cyclic aliphatic group, an aromatic group, a heterocycle, an ester group or an ether group; m and n are integers of 0 through 5; and a, b and c satisfy 0<a<1, 0<b<1, 0<c<1 and 0<a+b+c≦1.

5. A pattern formation material comprising:
a base polymer including a unit represented by Chemical Formula 2 and a unit represented by Chemical Formula 5; and
an acid generator: 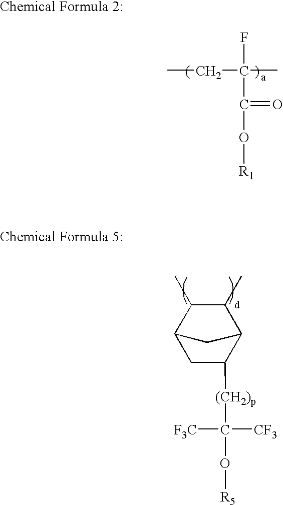
wherein R₁ is a protecting group released by an acid; R₅ is an alkyl group, a cyclic aliphatic group, an aromatic group, a heterocycle, an ester group or an ether group; p is an integer of 0 through 5; and a and d satisfy 0<a<1, 0<d<1 and 0<a+d≦1.

6. A pattern formation material comprising:
a base polymer including a unit represented by Chemical Formula 2 and a unit represented by Chemical Formula 6; and
an acid generator: 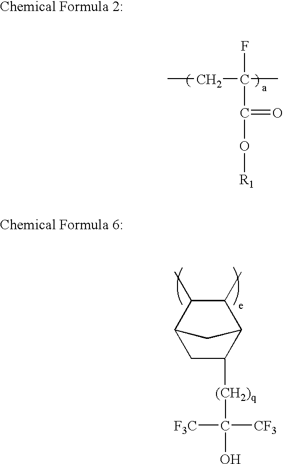
wherein R₁ is a protecting group released by an acid; q is an integer of 0 through 5; and a and e satisfy 0<a<1, 0<e<1 and 0<a+e≦1.

7. A pattern formation material comprising:
a base polymer including a unit represented by Chemical Formula 2, a unit represented by Chemical Formula 5 and a unit represented by Chemical Formula 6; and
an acid generator: 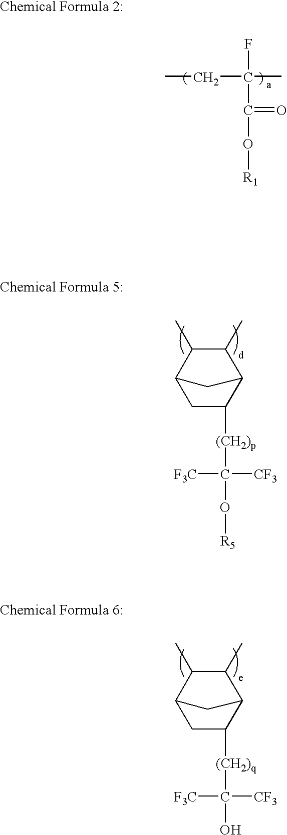
wherein R₁ is a protecting group released by an acid; R₅ is an alkyl group, a cyclic aliphatic group, an aromatic group, a heterocycle, an ester group or an ether group; p and q are integers of 0 through 5; and a, d and e satisfy 0<a<1, 0<d<1, 0<e<1 and 0<a+d+e≦1.

8. A pattern formation method comprising the steps of:
forming a resist film by applying, on a substrate, a pattern formation material containing a base polymer including a unit represented by Chemical Formula 1, and an acid generator: 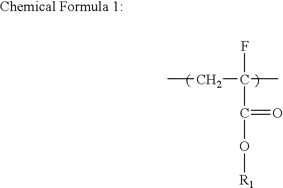
wherein R₁ is a protecting group released by an acid;
irradiating said resist film with exposing light of a wavelength not longer than a 180 nm band for pattern exposure; and
forming a resist pattern by developing said resist film after the pattern exposure.

9. The pattern formation method of claim 8,
wherein said exposing light is a Xe₂ laser beam, a F₂ laser beam, a Kr₂ laser beam, an ArKr laser beam or an Ar₂ laser beam.

10. The pattern formation method of claim 8,
wherein said exposing light is a soft X-ray beam.

11. The pattern formation method of claim 8,
wherein said exposing light is a hard X-ray beam.

12. A pattern formation method comprising the steps of:
forming a resist film by applying, on a substrate, a pattern formation material containing a base polymer including a unit represented by Chemical Formula 2 and a unit represented by Chemical Formula 3, and an acid generator: 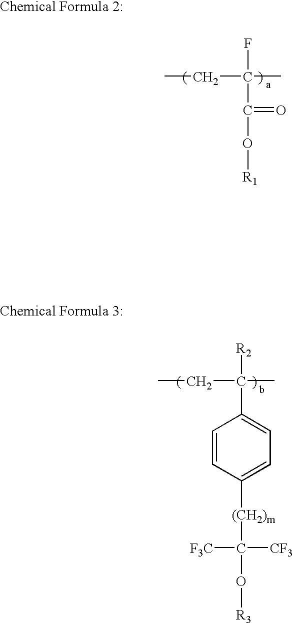
wherein R₁ is a protecting group released by an acid; R₂ is a hydrogen atom, a chlorine atom, a fluorine atom, an alkyl group or an alkyl group including a fluorine atom; R₃ is an alkyl group, a cyclic aliphatic group, an aromatic group, a heterocycle, an ester group or an ether group; m is an integer of 0 through 5; and a and b satisfy 0<a<1, 0<b<1 and 0<a+b≦1;
irradiating said resist film with exposing light of a wavelength not longer than a 180 nm band for pattern exposure; and
forming a resist pattern by developing said resist film after the pattern exposure.

13. The pattern formation method of claim 12,
wherein said exposing light is a Xe₂ laser beam, a F₂ laser beam, a Kr₂ laser beam, an ArKr laser beam or an Ar₂ laser beam.

14. The pattern formation method of claim 12,
wherein said exposing light is a soft X-ray beam.

15. The pattern formation method of claim 12,
wherein said exposing light is a hard X-ray beam.

16. A pattern formation method comprising the steps of:
forming a resist film by applying, on a substrate, a pattern formation material containing a base polymer including a unit represented by Chemical Formula 2 and a unit represented by Chemical Formula 4, and an acid generator: 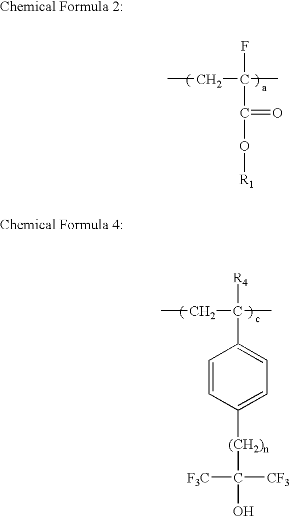
wherein R₁ is a protecting group released by an acid; R₄ is a hydrogen atom, a chlorine atom, a fluorine atom, an alkyl group or an alkyl group including a fluorine atom; n is an integer of 0 through 5; and a and c satisfy 0<a<1, 0<c<1 and 0<a+c≦1;
irradiating said resist film with exposing light of a wavelength not longer than a 180 nm band for pattern exposure; and
forming a resist pattern by developing said resist film after the pattern exposure.

17. The pattern formation method of claim 16,
wherein said exposing light is a Xe₂ laser beam, a F₂ laser beam, a Kr₂ laser beam, an ArKr laser beam or an Ar₂ laser beam.

18. The pattern formation method of claim 16,
wherein said exposing light is a soft X-ray beam.

19. The pattern formation method of claim 16,
wherein said exposing light is a hard X-ray beam.

20. A pattern formation method comprising the steps of:
forming a resist film by applying, on a substrate, a pattern formation material containing a base polymer including a unit represented by Chemical Formula 2, a unit represented by Chemical Formula 3 and a unit represented by Chemical Formula 4, and an acid generator: 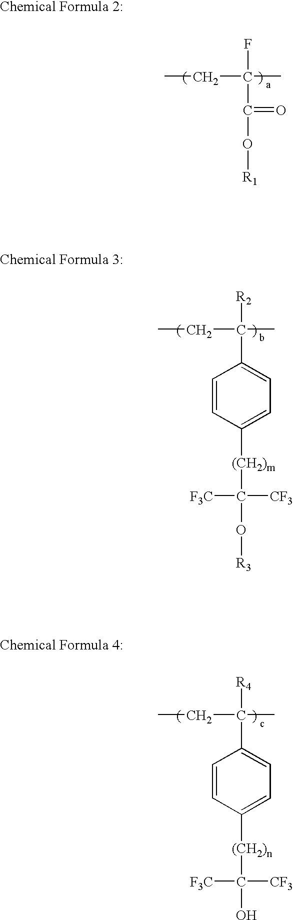
wherein R₁ is a protecting group released by an acid; R₂ and R₄ are the same or different and are selected from the group consisting of a hydrogen atom, a chlorine atom, a fluorine atom, an alkyl group and an alkyl group including a fluorine atom; R₃ is an alkyl group, a cyclic aliphatic group, an aromatic group, a heterocycle, an ester group or an ether group; m and n are integers of 0 through 5; and a, b and c satisfy 0<a<1, 0<b<1, 0<c<1 and 0<a+b+c≦1;
irradiating said resist film with exposing light of a wavelength not longer than a 180 nm band for pattern exposure; and
forming a resist pattern by developing said resist film after the pattern exposure.

21. The pattern formation method of claim 20,
wherein said exposing light is a Xe₂ laser beam, a F₂ laser beam, a Kr₂ laser beam, an ArKr laser beam or an Ar₂ laser beam.

22. The pattern formation method of claim 20,
wherein said exposing light is a soft X-ray beam.

23. The pattern formation method of claim 20,
wherein said exposing light is a hard X-ray beam.

24. A pattern formation method comprising the steps of:
forming a resist film by applying, on a substrate, a pattern formation material containing a base polymer including a unit represented by Chemical Formula 2 and a unit represented by Chemical Formula 5, and an acid generator: 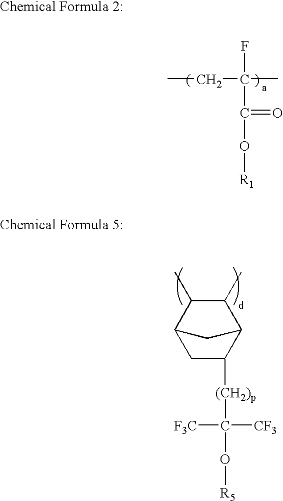
wherein R₁ is a protecting group released by an acid; R₅ is an alkyl group, a cyclic aliphatic group, an aromatic group, a heterocycle, an ester group or an ether group; p is an integer of 0 through 5; and a and d satisfy 0<a<1, 0<d<1 and 0<a+d≦1;
irradiating said resist film with exposing light of a wavelength not longer than a 180 nm band for pattern exposure; and
forming a resist pattern by developing said resist film after the pattern exposure.

25. The pattern formation method of claim 24,
wherein said exposing light is a Xe₂ laser beam, a F₂ laser beam, a Kr₂ laser beam, an ArKr laser beam or an Ar₂ laser beam.

26. The pattern formation method of claim 24,
wherein said exposing light is a soft X-ray beam.

27. The pattern formation method of claim 24,
wherein said exposing light is a hard X-ray beam.

28. A pattern formation method comprising the steps of:
forming a resist film by applying, on a substrate, a pattern formation material containing a base polymer including a unit represented by Chemical Formula 2 and a unit represented by Chemical Formula 6, and an acid generator: 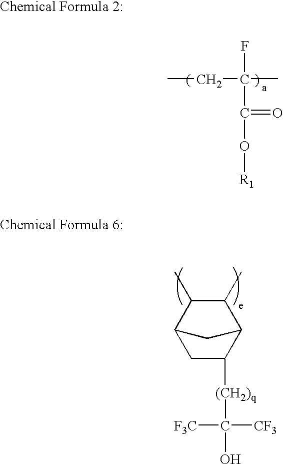
wherein R₁ is a protecting group released by an acid; q is an integer of 0 through 5; and a and e satisfy 0<a<1, 0<e<1 and 0<a+e≦1;
irradiating said resist film with exposing light of a wavelength not longer than a 180 nm band for pattern exposure; and
forming a resist pattern by developing said resist film after the pattern exposure.

29. The pattern formation method of claim 28,
wherein said exposing light is a Xe₂ laser beam, a F₂ laser beam, a Kr₂ laser beam, an ArKr laser beam or an Ar₂ laser beam.

30. The pattern formation method of claim 28,
wherein said exposing light is a soft X-ray beam.

31. The pattern formation method of claim 28,
wherein said exposing light is a hard X-ray beam.

32. A pattern formation method comprising the steps of:
forming a resist film by applying, on a substrate, a pattern formation material containing a base polymer including a unit represented by Chemical Formula 2, a unit represented by Chemical Formula 5 and a unit represented by Chemical Formula 6, and an acid generator: 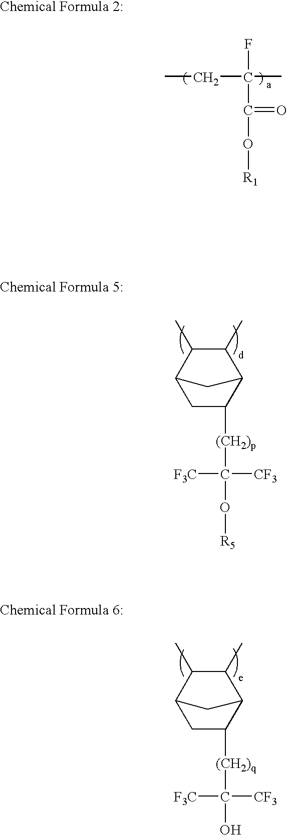
wherein R₁ is a protecting group released by an acid; R₅ is an alkyl group, a cyclic aliphatic group, an aromatic group, a heterocycle, an ester group or an ether group; p and q are integers of 0 through 5; and a, d and e satisfy 0<a<1, 0<d<1, 0<e<1 and 0<a+d+e≦1;
irradiating said resist film with exposing light of a wavelength not longer than a 180 nm band for pattern exposure; and
forming a resist pattern by developing said resist film after the pattern exposure.

33. The pattern formation method of claim 32,
wherein said exposing light is a Xe₂ laser beam, a F₂ laser beam, a Kr₂ laser beam, an ArKr laser beam or an Ar₂ laser beam.

34. The pattern formation method of claim 32,
wherein said exposing light is a soft X-ray beam.

35. The pattern formation method of claim 32,
wherein said exposing light is a hard X-ray beam.
